(19) United States
(12) Patent Application Publication
(10) Pub. No.: US 2011/0133308 A1
(43) Pub. Date: Jun. 9, 2011

(54) SEMICONDUCTOR DEVICE WITH OXIDE DEFINE PATTERN

(76) Inventors: Kuei-Ti Chan, Hsinchu City (TW); Tung-Hsing Lee, Taipei County (TW); Augusto Marques, Moscavide (PT); Wen-Chang Lee, Taipei City (TW)

(21) Appl. No.: 13/029,066

(22) Filed: Feb. 16, 2011

Related U.S. Application Data
(63) Continuation-in-part of application No. 12/703,787, filed on Feb. 11, 2010.
(60) Provisional application No. 61/180,481, filed on May 22, 2009.
(60) Provisional application No. 61/321,965, filed on Apr. 8, 2010.

(51) Int. Cl. H01L 29/86

(52) U.S. Cl. 257/531; 257/E29.325

(57) ABSTRACT

A semiconductor device includes a substrate; an inductor wiring pattern overlying the substrate, wherein the inductor wiring pattern is formed in an inductor-forming region; a plurality of shielding patterns between the inductor wiring pattern and the substrate within the inductor-forming region; and at least one first oxide define (OD) pattern disposed in the substrate or between the inductor wiring pattern and the substrate.

### CROSS REFERENCE TO RELATED APPLICATIONS

This is a continuation-in-part of U.S. application Ser. No. 12/703,787 filed Feb. 11, 2010, which claims the priority of U. S. application No. 61/180,481 filed May 22, 2009. This application also claims the benefits from U.S. provisional application No. 61/321,965 filed Apr. 8, 2010.

### BACKGROUND OF THE INVENTION

1. Field of the Invention

The present invention relates generally to a semiconductor device. More particularly, the present invention relates to a semiconductor device with oxide define (OD) pattern.

2. Description of the Prior Art

The fast growing of the wireless market has created an urgent demand for smaller and cheaper handsets with increased functionality and performance. A major trend of circuit design is to incorporate as many circuit components into integrated circuit form as possible, whereby cost per wafer can be reduced.

Passive devices such as inductors built in semiconductor wafers are widely used in CMOS based radio frequency (RF) circuits such as low-noise amplifiers, voltage-controlled oscillators and power amplifiers. An inductor is a passive electronic component that stores energy in the form of a magnetic field, and an inductor tends to resist any change in the amount of current flowing through it. One of the most important characteristics of the inductor is the quality factor Q, which relates to the performance of the RF or other circuits and systems. The quality factor Q of an integrated circuit is limited by parasitic losses within the substrate itself. These losses include high resistance through metal layers of the inductor itself and substrate loss. Consequently, in order to achieve a high quality factor, resistance within the inductor and substrate loss should be held to a minimum.

In a conventional semiconductor chip, it has been found that the presence of dummy feature causes detrimental impact on the operation of an inductor of the semiconductor chip. Typically, to prevent the degradation of the inductor's performance, disposition of dummy features such as dummy metal patterns are forbidden within the inductor-forming region according to the design rule. It has been observed that an undesired cold trend or performance degradation occurs to the active devices such as MOS transistors which are proximate to the inductor-forming region based on 65 nm technology node or beyond. Therefore, there is a need in this industry to provide an improved method or improved semiconductor device design to eliminate the adverse effects on the active devices which are proximate to the inductor-forming region.

### SUMMARY OF THE INVENTION

It is one objective of the invention to provide a semiconductor device, which is capable of eliminating the adverse effects on the active devices that are proximate to the inductor-forming region.

According to one embodiment of the invention, a semiconductor device includes a substrate; an inductor wiring pattern on the substrate; and at least one oxide define (OD) dummy feature disposed in the substrate under the inductor wiring pattern.

According to another embodiment of the invention, a semiconductor device includes a substrate; an inductor wiring pattern on the substrate; at least one first oxide define (OD) dummy feature disposed in the substrate within an inductor-forming region under the inductor wiring pattern; and at least one second OD dummy feature disposed in the substrate within a peripheral region that is proximate to the inductor-forming region.

According to yet another embodiment of the invention, a semiconductor device includes a substrate; an inductor wiring pattern on the substrate within an inductor-forming region; and at least one oxide define (OD) dummy feature disposed in the substrate within a peripheral region that is proximate to the inductor-forming region.

According to still another embodiment of the invention, a semiconductor device includes a substrate; an inductor wiring pattern overlying the substrate, wherein the inductor wiring pattern is formed in an inductor-forming region; a plurality of shielding patterns between the inductor wiring pattern and the substrate within the inductor-forming region; and at least one first oxide define (OD) pattern disposed in the substrate or between the inductor wiring pattern and the substrate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 illustrates a top view of an exemplary semiconductor device according to one embodiment of the invention;

FIG. 2 is a sectional view taken along line I-I′ of FIG. 1;

FIG. 3 illustrates a top view of an exemplary semiconductor device according to another embodiment of the invention;

FIG. 4 is a sectional view taken along line I-I′ of FIG. 3;

FIG. 5 illustrates a top view of an exemplary semiconductor device according to yet another embodiment of the invention;

FIG. 6 illustrates a top view of an exemplary semiconductor device according to still another embodiment of the invention;

FIG. 7 is a sectional view taken along line II-II′ of FIG. 6; and

FIG. 8 illustrates a sectional view of an exemplary semiconductor device according to yet another embodiment of the invention.

### DETAILED DESCRIPTION

In the following detailed description, reference is made to the accompanying drawings, which form a part hereof, and in which is shown by way of illustration specific embodiments in which the invention may be practiced. These embodiments are described in sufficient detail to enable those skilled in the art to practice the invention, and it is to be understood that other embodiments may be utilized and that structural, logical and electrical changes may be made without departing from the spirit and scope of the present invention. The following detailed description is, therefore, not to be taken in a limiting sense, and the scope of the present invention is defined by the appended claims.

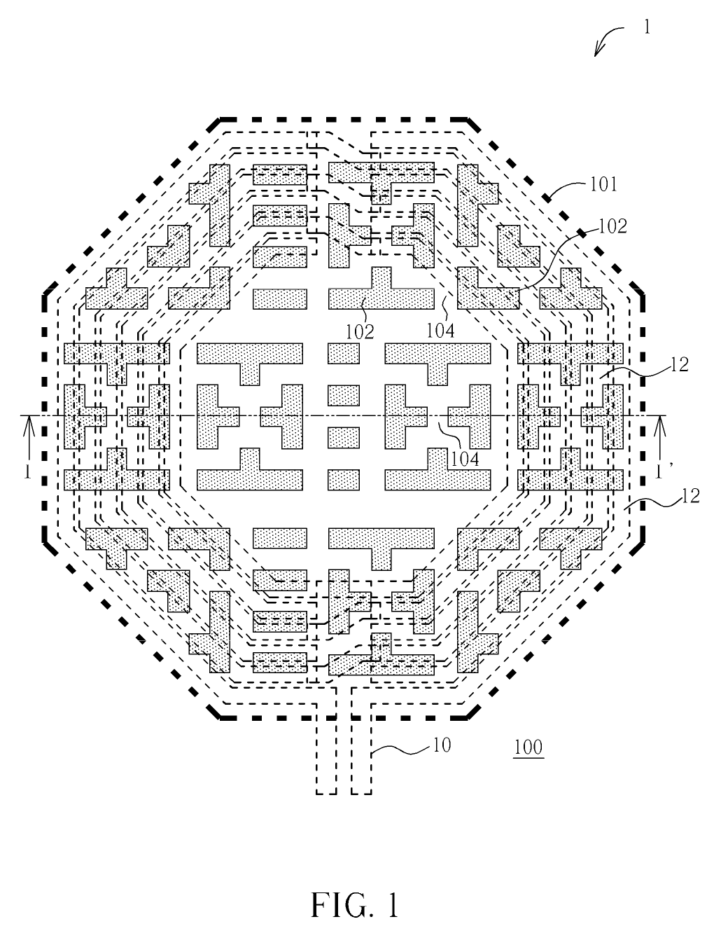

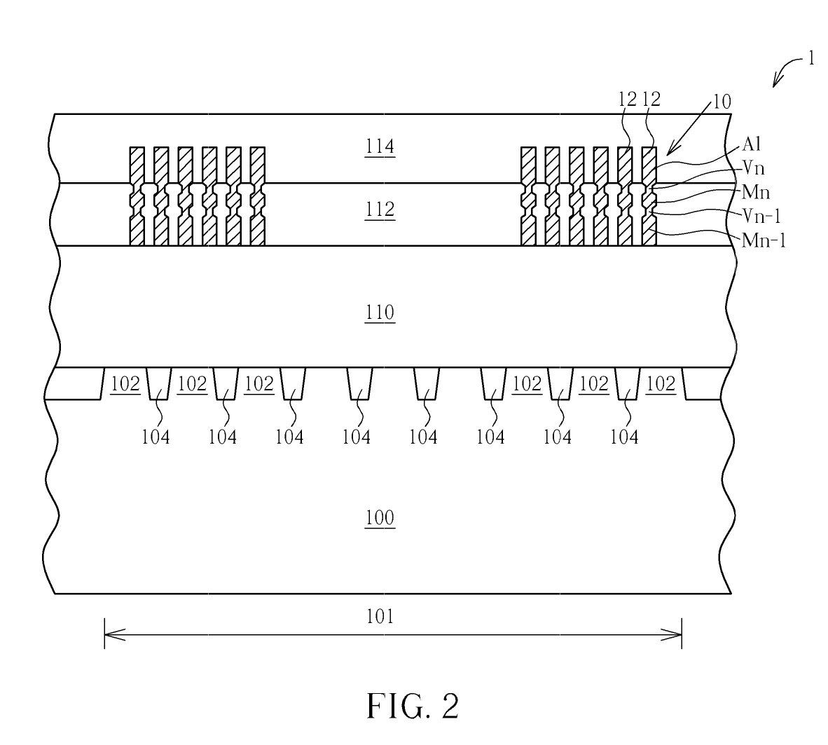

FIG. 1 illustrates a top view of an exemplary semiconductor device 1 according to one embodiment of the invention. The semiconductor device 1 includes a substrate 100, an inductor wiring pattern 10 on the substrate 100 and at least one oxide define (OD) dummy feature 102 disposed in the substrate 100 under the inductor wiring pattern 10. In some embodiments or applications, OD dummy is called diffusion dummy. The inductor wiring pattern 10 may have with multi-turn windings. In other embodiments, the inductor wiring pattern 10 could be a portion of a transformer. FIG. 2 is a sectional view taken along line I-I′ of FIG. 1. It is understood that although the inductor wiring pattern 10 of the embodiment is demonstrated in the form of octagonal shape, it can also be formed of any other suitable shapes, for example, spiral shape, circular shape, rectangular shape, etc. The shape or pattern in which the inductor wiring is realized is not meant to be any limit. The invention is also applicable to single-ended type inductors, differential inductors, stacked inductors, etc.

As shown in FIG. 1 and FIG. 2, in this embodiment, each winding 12 of the inductor wiring pattern 10 may have a vertical metal stack includes, in the order of, metal layer Mₙ₋₁, via plug layer Vₙ₋₁, metal layer Mₙ, via plug layer Vₙ and an aluminum layer. However, any suitable layers could be utilized to form the inductor wiring pattern 10. The via plug layer Vₙ₋₁ electrically connects the metal layer Mₙ₋₁ to the overlying metal layer Mₙ, while the via plug layer Vₙ electrically connects the metal layer Mₙ to the overlying aluminum layer. According to the embodiment, the winding 12 of the inductor wiring pattern 10 does not include lower metal levels M₁˜Mₙ₋₂ in order to reduce parasitic coupling to the substrate 100. The metal layer Mₙ₋₁, via plug layer Vₙ₋₁ and metal layer Mₙ may be formed by conventional copper damascene methods such as single damascene methods or dual damascene methods. For example, the metal layer Mₙ₋₁ may be formed by single damascene methods, while the metal layer Mₙ and the integral via plug layer Vₙ₋₁ may be formed by dual damascene methods. Then the metal layer Mₙ and the via plug layer Vₙ₋₁ may be unitary.

Multiple layers of dielectric 110˜114 could be provided on the substrate 100. According to the embodiment, the inductor wiring pattern 10 is basically fabricated above the dielectric layer 110 that is interposed between the overlying dielectric layer 112 and the substrate 100. For example, the metal layer Mₙ₋₁, via plug layer Vₙ₋₁, metal layer Mₙ, and via plug layer Vₙ could be inlaid into the dielectric layer 112. The aluminum layer could be formed in the dielectric layer 114. The dielectric layers 110 and 112 may comprise silicon oxide, silicon nitride, silicon carbide, silicon oxy-nitride, low-k or ultra low-k (ULK) materials such as organic (e.g., SiLK) or inorganic (e.g., HSQ). The dielectric layer 114 may comprise silicon oxide, silicon nitride, silicon carbide, silicon oxy-nitride, polyimide or the like.

At least one oxide define (OD) dummy feature 102 is disposed in the substrate 100. The OD dummy features 102 are disposed within an inductor-forming region 101 that is under the inductor wiring pattern 10. In one embodiment, the OD dummy features 102 could be further disposed near at least one active device (not shown), such as a MOS transistor, around the semiconductor device 1. In one embodiment, the active device and the inductor wiring pattern 10 could be located in different levels. In another embodiment, at least a portion of the active device and at least a portion of the inductor wiring pattern 10 could be located in the same level. The OD dummy features 102 under the inductor wiring pattern 10 help alleviate the performance degradation of the active device, which may originate from the proximity of the active device to the inductor-forming region 101. According to the embodiment of this invention, the OD dummy features 102 occupy at least 5% of a predetermined area under the inductor wiring pattern 10. In one embodiment, the predetermined area could be about 100-250,000 μm². However, the percentage of area the OD dummy features 102 occupy depends on the design requirements and no hard rules should be set. Even only one OD dummy feature 102 is present under the inductor wiring pattern 10 may help alleviate the performance degradation of the active device. In one embodiment, no dopant is implanted into the OD dummy features 102. That is, an LDD block mask and source/drain (S/D) implant block mask may be provided to cover the inductor wiring pattern 10 during the LDD implant and S/D implant respectively. However, it is understood that in some cases, dopants such as N type or P type dopants can be implanted into the OD dummy features 102. According to the embodiment of this invention, no silicide is formed on the OD dummy features 102. The OD dummy features 102 may be surrounded by a shallow trench isolation (STI) pattern 104 within the inductor-forming region 101 under the inductor wiring pattern 10.

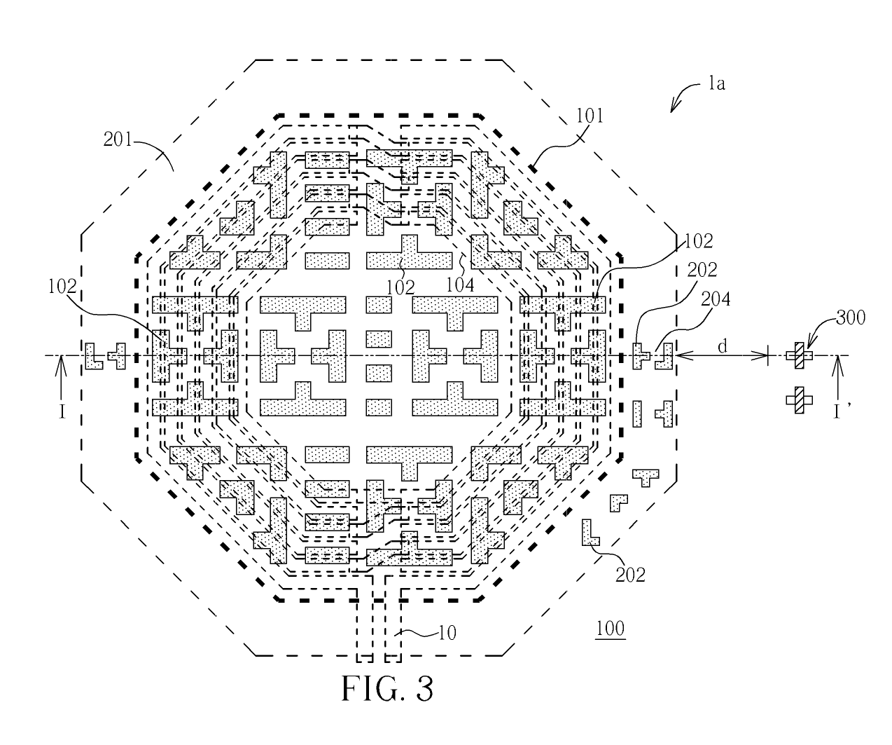

FIG. 3 illustrates a top view of an exemplary semiconductor device 1a according to another embodiment of the invention. The semiconductor device 1a includes a substrate 100, an inductor wiring pattern 10 on the substrate 100, at least one first oxide define (OD) dummy feature 102 disposed in the substrate 100 within an inductor-forming region 101 under the inductor wiring pattern 10 and at least one second OD dummy feature 202 disposed in the substrate 100 within a peripheral region 201 that is proximate to the inductor-forming region 101. In some embodiments or applications, OD dummy is called diffusion dummy. The inductor wiring pattern 10 may have with multi-turn windings. In other embodiments, the inductor wiring pattern 10 could be a portion of a transformer.

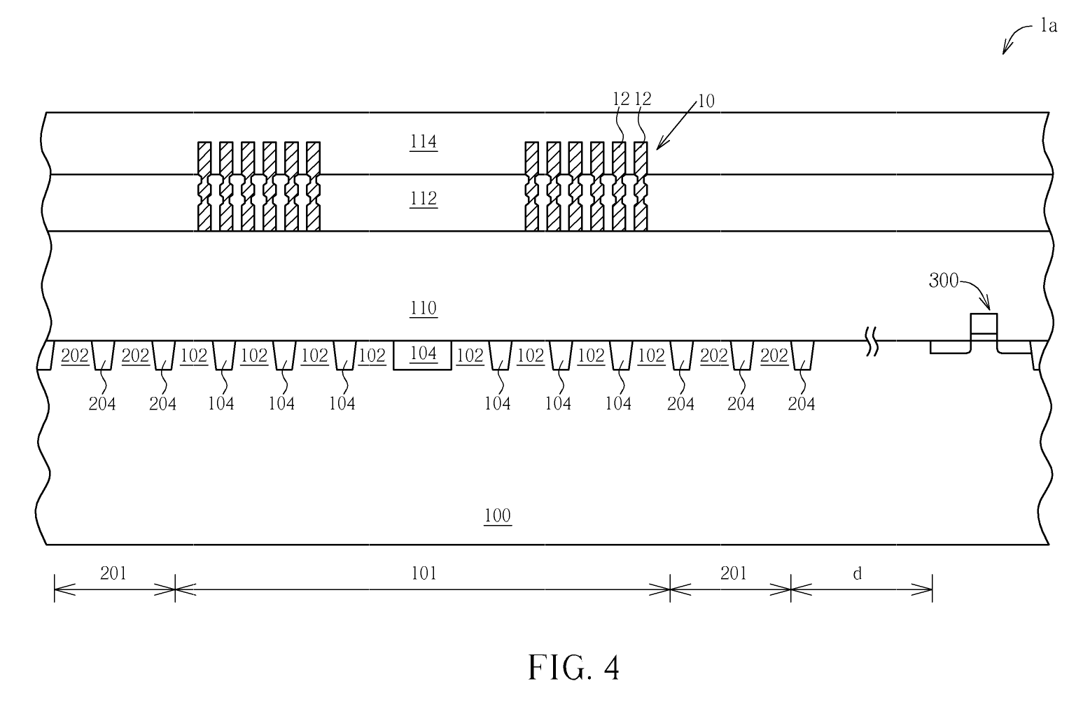

FIG. 4 is a sectional view taken along line I-I′ of FIG. 3, wherein like numerals designate like elements, layers or regions. As shown in FIG. 3 and FIG. 4, likewise, each winding 12 of the inductor wiring pattern 10 may have a vertical metal stack includes, in the order of, metal layer Mₙ₋₁, via plug layer Vₙ₋₁, metal layer Mₙ, via plug layer Vₙ and an aluminum layer. However, any suitable layers may be utilized to form the inductor wiring pattern 10. The via plug layer Vₙ₋₁ electrically connects the metal layer Mₙ₋₁ to the overlying metal layer Mₙ, while the via plug layer Vₙ electrically connects the metal layer Mₙ to the overlying aluminum layer. According to the embodiment, the winding 12 of the inductor wiring pattern 10 does not include lower metal levels M₁˜Mₙ₋₂ in order to reduce parasitic coupling to the substrate 100. The metal layer Mₙ₋₁, via plug layer Vₙ₋₁ and metal layer Mₙ may be formed by conventional copper damascene methods such as single damascene methods or dual damascene methods. For example, the metal layer Mₙ₋₁ may be formed by single damascene methods, while the metal layer Mₙ and the integral via plug layer Vₙ₋₁ may be formed by dual damascene methods. Then the metal layer Mₙ and the via plug layer Vₙ₋₁ may be unitary.

Multiple layers of dielectric 110-114 could be provided on the substrate 100. According to the embodiment, the inductor wiring pattern 10 is basically fabricated above the dielectric layer 110 that is interposed between the overlying dielectric layer 112 and the substrate 100. For example, the metal layer M_{n-1, via plug layer V}ₙ₋₁, metal layer Mₙ, and via plug layer Vₙ could be inlaid into the dielectric layer 112. The aluminum layer could be formed in the dielectric layer 114. The dielectric layers 110 and 112 may comprise silicon oxide, silicon nitride, silicon carbide, silicon oxy-nitride, low-k or ultra low-k (ULK) materials such as organic (e.g., SiLK) or inorganic (e.g., HSQ). The dielectric layer 114 may comprise silicon oxide, silicon nitride, silicon carbide, silicon oxy-nitride, polyimide or the like.

At least one oxide define (OD) dummy feature 102 is disposed in the substrate 100 within an inductor-forming region 101 that is under the inductor wiring pattern 10. According to the embodiment of this invention, the OD dummy features 102 occupy at least 5% of a predetermined area under the inductor wiring pattern 10. In one embodiment, the predetermined area could be about 100-250,000 μm². However, the percentage of area the OD dummy features 102 occupy depends on the design requirements and no hard rules should be set. Even only one OD dummy feature 102 is present under the inductor wiring pattern 10 may help alleviate the performance degradation of the active device. In one embodiment, no dopant is implanted into the OD dummy features 102. That is, an LDD block mask and source/drain (S/D) implant block mask may be provided to cover the inductor wiring pattern 10 during the LDD implant and S/D implant respectively. However, it is understood that in some cases, dopants such as N type or P type dopants can be implanted into the OD dummy features 102. According to the embodiment of this invention, no silicide is formed on the OD dummy features 102. The OD dummy features 102 may be surrounded by the STI pattern 104 within the inductor-forming region 101 under the inductor wiring pattern 10.

At least one OD dummy feature 202 is disposed in the substrate 100 within a peripheral region 201 that is proximate to the inductor-forming region 101. According to the embodiment of this invention, the peripheral region 201 is an annular region. However, the peripheral region 201 could be of any other shapes. According to the embodiment of this invention, for example, a width of the peripheral region 201 may range between 0 and 50 micrometers from an edge of the inductor-forming region 101. According to the embodiment of this invention, active devices 300 could be formed a distance d away from the peripheral region 201. According to the embodiment of this invention, the aforesaid distance d is less than 20 micrometers. However, the magnitude of the distance d depends on design requirements and no hard rules should be set. In one embodiment, the active devices 300 and the inductor wiring pattern 10 could be located in different levels. In another embodiment, at least a portion of the active device 300 and at least a portion of the inductor wiring pattern 10 could be located in the same level. In one embodiment, no dopant is implanted into the OD dummy features 202. That is, an LDD block mask and source/drain (S/D) implant block mask may be provided to cover the peripheral region 201 during the LDD implant and S/D implant respectively. However, it is understood that in some cases, dopants such as N type or P type dopants can be implanted into the OD dummy features 202. According to the embodiment of this invention, no silicide is formed on the OD dummy features 202. The OD dummy features 202 may be surrounded by the STI pattern 204. The STI pattern 204 could be disposed within the peripheral region 201.

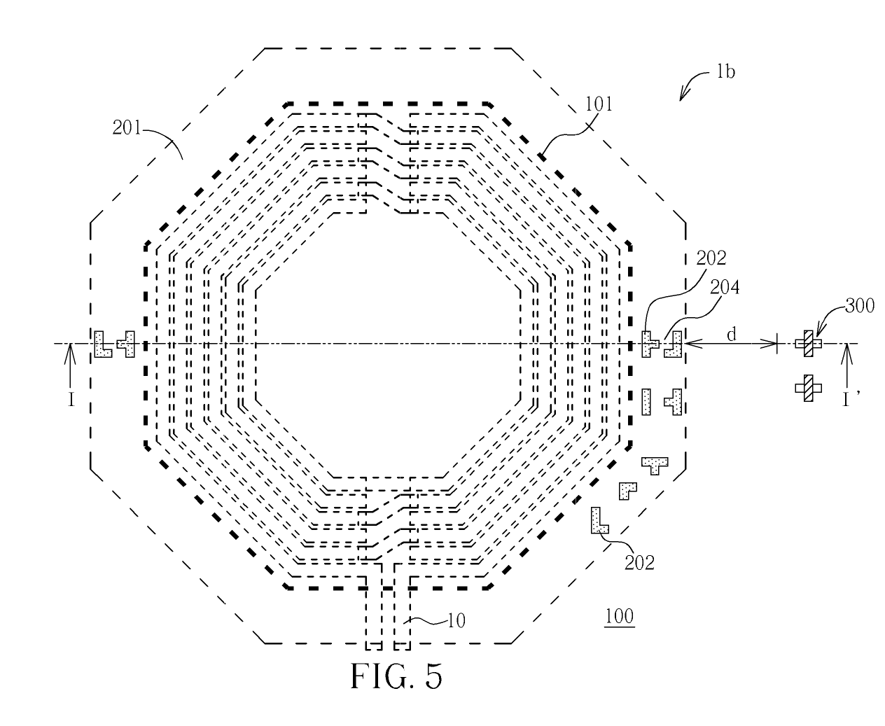

FIG. 5 illustrates a top view of an exemplary semiconductor device 1b according to yet another embodiment of the invention. Likewise, the semiconductor device 1b includes a substrate 100 and an inductor wiring pattern 10 on the substrate 100 within an inductor-forming region 101. According to the embodiment of this invention, no oxide define (OD) dummy feature is disposed in the substrate 100 within the inductor-forming region 101. According to the embodiment of this invention, at least one OD dummy feature 202 is disposed in the substrate 100 within a peripheral region 201 that is proximate to the inductor-forming region 101. According to the embodiment of this invention, the peripheral region 201 is an annular region. However, the peripheral region 201 could be of any other shapes. According to the embodiment of this invention, for example, a width of the peripheral region 201 may range between 0 and 50 micrometers from an edge of the inductor-forming region 101. The OD dummy feature 202 may be surrounded by the STI pattern 204. The STI pattern 204 could be disposed within the peripheral region 201.

According to the embodiment of this invention, active devices 300 could be formed a distance d away from the peripheral region 201. According to the embodiment of this invention, the aforesaid distance d is less than 20 micrometers. However, the magnitude of the distance d depends on design requirements and no hard rules should be set. In one embodiment, the active devices 300 and the inductor wiring pattern 10 could be located in different levels. In another embodiment, at least a portion of the active device 300 and at least a portion of the inductor wiring pattern 10 could be located in the same level. In one embodiment, no dopant is implanted into the OD dummy features 202. That is, an LDD block mask and source/drain (S/D) implant block mask may be provided to cover the peripheral region 201 during the LDD implant and S/D implant respectively. However, it is understood that in some cases, dopants such as N type or P type dopants can be implanted into the OD dummy features 202. According to the embodiment of this invention, no silicide is formed on the OD dummy features 202.

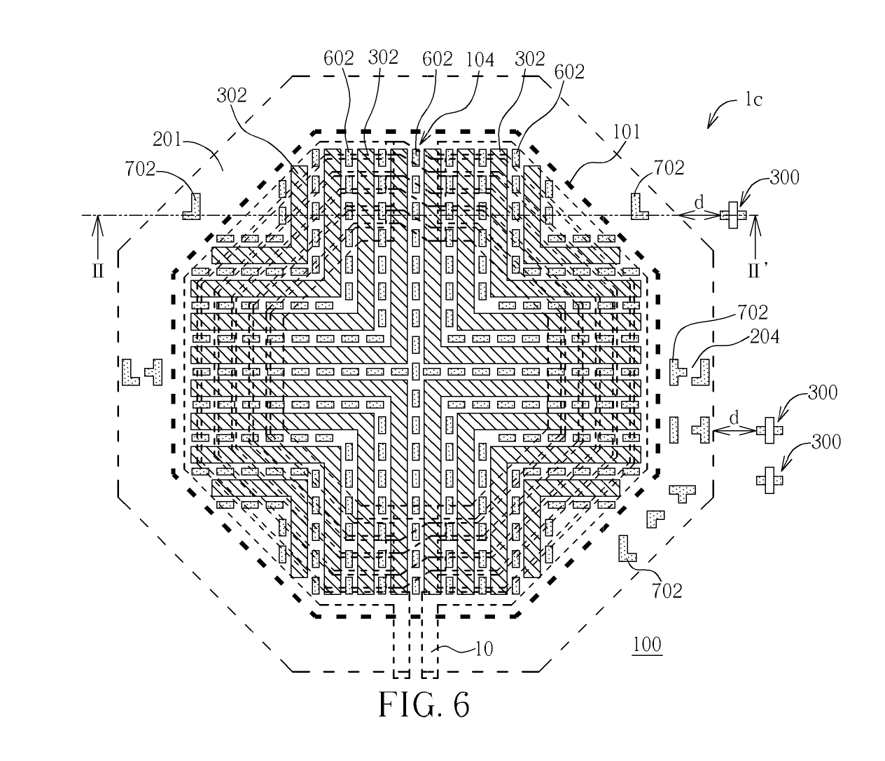

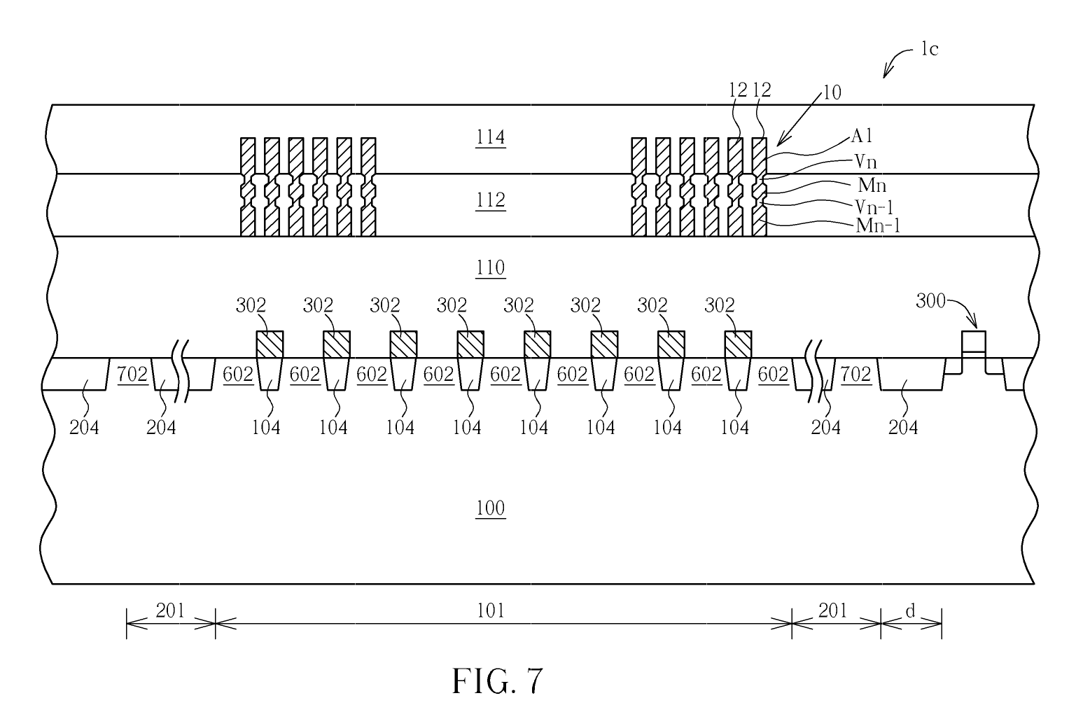

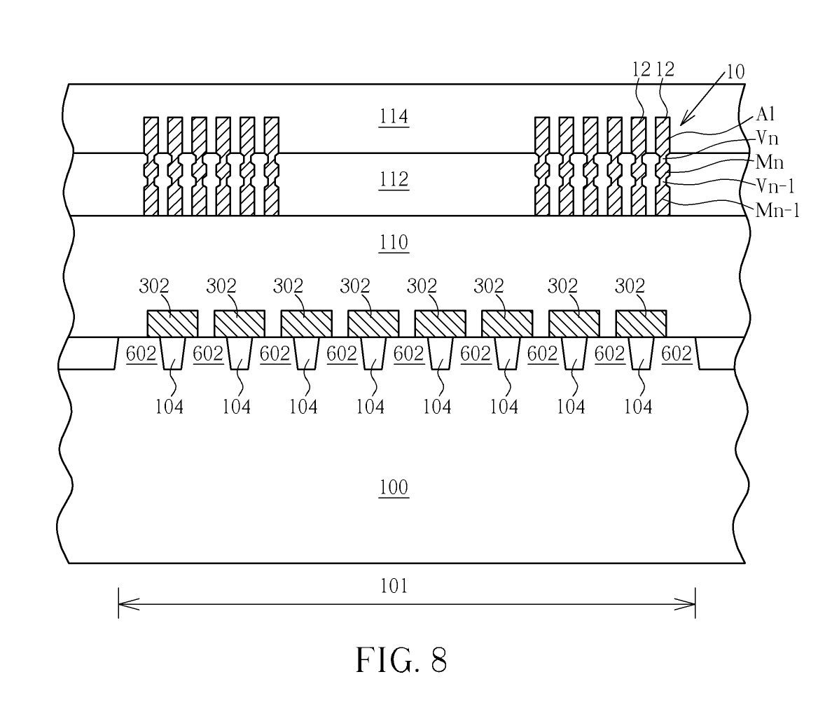

FIG. 6 illustrates a top view of an exemplary semiconductor device 1c according to still another embodiment of the invention. FIG. 7 is a sectional view taken along line II-II′ of FIG. 6, wherein like numerals designate like elements, layers or regions. As shown in FIGS. 6 and 7, the semiconductor device 1c includes a substrate 100 and an inductor wiring pattern 10 overlying the substrate 100 within an inductor-forming region 101. According to the embodiment of this invention, shielding patterns 302 are disposed within the inductor-forming region 101 underlying the inductor wiring pattern 10. The shielding patterns 302 can also be disposed outside the inductor-forming region 101 or in both inside and outside of the inductor-forming region 101. The shielding patterns 302 may act as a patterned ground shield (PGS) between the inductor wiring pattern 10 and the substrate 100, which diminish the substrate capacitance. The shielding patterns 302 can be grounded and thus prevents the performance of inductor wiring pattern 10 from being degraded by high frequency loss caused by the substrate 100. It has been known that the patterned shape of the shield eliminates eddy currents. According to the embodiment of this invention, the shielding patterns 302 may be line-shaped, L-shaped, rectangular-shaped or irregular-shaped, but not limited thereto. The shielding patterns 302 may be composed of conductive material such as polysilicon or metal. According to the embodiment of this invention, the shielding patterns 302 are disposed on or over the STI patterns 104. Though the shielding patterns 302 shown in FIG. 7 are disposed on the STI patterns 104, they could be disposed over the STI patterns 104 with other layers or materials, such as oxide layer, between them and the STI patterns 104. According to the embodiment of this invention, at least one oxide define (OD) pattern 602 is disposed in the substrate 100 or between the inductor wiring pattern 10 and the substrate 100. Though the OD pattern 602 shown in FIG. 7 is located in a lower level than the shielding patterns 302 are, the OD pattern 602 and the shielding patterns 302 can be located in the same level or different levels. The OD pattern 602 can be disposed between the shielding patterns 302. The OD pattern 602 can be a dummy feature or a portion of a device. According to the embodiment of this invention, the shielding patterns 302 do not overlap with the OD pattern 602. However, it is understood that, in some cases, the shielding patterns 302 may overlap with the OD pattern 602, as shown in FIG. 8, or fully cover the OD pattern 602.

According to the embodiment of this invention, at least one OD pattern 702 may be disposed in the substrate 100 or between the inductor wiring pattern 10 and the substrate 100 within a peripheral region 201 that is proximate to the inductor-forming region 101. Though the OD pattern 702 shown in FIG. 7 is located in a lower level than the shielding patterns 302 are, the OD pattern 702 and the shielding patterns 302 can be located in the same level or different levels. According to the embodiment of this invention, the peripheral region 201 is an annular region. However, the peripheral region 201 could be of any other shapes. According to the embodiment of this invention, for example, a width of the peripheral region 201 may range between 0 and 50 micrometers from an edge of the inductor-forming region 101. The OD pattern 702 may be surrounded by the STI pattern 204. The STI pattern 204 could be disposed within the peripheral region 201. According to the embodiment of this invention, active devices 300 could be formed a distance d away from the outline of the peripheral region 201. According to the embodiment of this invention, the aforesaid distance d is less than 20 micrometers. According to one embodiment of this invention, the OD pattern 602 is disposed near an active device 300 around the semiconductor device 1c. The shielding patterns 302 and a gate of the active device 300 may be made of the same layer such as polysilicon layer.

As can be seen in FIG. 7, likewise, each winding 12 of the inductor wiring pattern 10 may have a vertical metal stack includes, in the order of, metal layer Mₙ₋₁, via plug layer Vₙ₋₁, metal layer Mₙ, via plug layer Vₙ and an aluminum layer. However, any suitable layers may be utilized to form the inductor wiring pattern 10. The via plug layer Vₙ₋₁ electrically connects the metal layer Mₙ₋₁ to the overlying metal layer Mₙ, while the via plug layer Vₙ electrically connects the metal layer Mₙ to the overlying aluminum layer. According to the embodiment, the winding 12 of the inductor wiring pattern 10 does not include lower metal levels M₁˜Mₙ₋₂ in order to reduce parasitic coupling to the substrate 100. The metal layer Mₙ₋₁, via plug layer Vₙ₋₁ and metal layer Mₙ may be formed by conventional copper damascene methods such as single damascene methods or dual damascene methods. For example, the metal layer Mₙ₋₁ may be formed by single damascene methods, while the metal layer Mₙ and the integral via plug layer Vₙ₋₁ may be formed by dual damascene methods. Then the metal layer Mₙ and the via plug layer Vₙ₋₁ may be unitary.

Multiple layers of dielectric 110-114 could be provided on the substrate 100. According to the embodiment, the inductor wiring pattern 10 is basically fabricated above the dielectric layer 110 that is interposed between the overlying dielectric layer 112 and the substrate 100. For example, the metal layer Mₙ₋₁, via plug layer Vₙ₋₁, metal layer Mₙ, and via plug layer Vₙ could be inlaid into the dielectric layer 112. The aluminum layer could be formed in the dielectric layer 114. The dielectric layers 110 and 112 may comprise silicon oxide, silicon nitride, silicon carbide, silicon oxy-nitride, low-k or ultra low-k (ULK) materials such as organic (e.g., SiLK) or inorganic (e.g., HSQ). The dielectric layer 114 may comprise silicon oxide, silicon nitride, silicon carbide, silicon oxy-nitride, polyimide or the like.

According to the embodiment of this invention, the OD patterns 602 occupy at least 5% of a predetermined area under the inductor wiring pattern 10. In one embodiment, the predetermined area could be about 100-250,000 μm². However, the percentage of area the OD patterns 602 occupy depends on the design requirements and no hard rules should be set. Even only one OD pattern 602 is present under the inductor wiring pattern 10 may help alleviate the performance degradation of the active device. In one embodiment, no dopant is implanted into the OD patterns 602. That is, an LDD block mask and source/drain (S/D) implant block mask may be provided to cover the inductor wiring pattern 10 during the LDD implant and S/D implant respectively. However, it is understood that in some cases, dopants such as N type or P type dopants can be implanted into the OD patterns 602. According to the embodiment of this invention, no silicide is formed on the OD patterns 602. The OD patterns 602 may be surrounded by the STI pattern 104 within the inductor-forming region 101 under the inductor wiring pattern 10. Similarly, in one embodiment, no dopant is implanted into the OD patterns 702. That is, an LDD block mask and source/drain (S/D) implant block mask may be provided to cover the peripheral region 201 during the LDD implant and S/D implant respectively. However, it is understood that in some cases, dopants such as N type or P type dopants can be implanted into the OD patterns 702. According to the embodiment of this invention, no silicide is formed on the OD patterns 702. The OD patterns 702 may be surrounded by the STI pattern 204 within the peripheral region 201.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device comprising:
a substrate;
an inductor wiring pattern overlying the substrate, wherein the inductor wiring pattern is formed in an inductor-forming region;
a plurality of shielding patterns between the inductor wiring pattern and the substrate within the inductor-forming region; and
at least one first oxide define (OD) pattern disposed in the substrate or between the inductor wiring pattern and the substrate.

2. The semiconductor device according to claim 1 wherein the semiconductor device further comprises a shallow trench isolation (STI) pattern under the inductor wiring pattern.

3. The semiconductor device according to claim 2 wherein the STI pattern surrounds the OD pattern.

4. The semiconductor device according to claim 2 wherein the shielding patterns is disposed on or over the STI pattern.

5. The semiconductor device according to claim 1 wherein the shielding patterns do not overlap with the OD pattern.

6. The semiconductor device according to claim 1 wherein no dopant is implanted into the OD pattern.

7. The semiconductor device according to claim 1 wherein an N type dopant is implanted into the OD pattern.

8. The semiconductor device according to claim 1 wherein a P type dopant is implanted into the OD pattern.

9. The semiconductor device according to claim 1 wherein no silicide is formed on the OD pattern.

10. The semiconductor device according to claim 1 wherein a dielectric is provided between the substrate and the inductor wiring pattern.

11. The semiconductor device according to claim 1 wherein the OD pattern is disposed in the substrate or between the inductor wiring pattern and the substrate within the inductor-forming region, and wherein a peripheral region is proximate to the inductor-forming region.

12. The semiconductor device according to claim 11 wherein a width of the peripheral region ranges between 0 and 50 micrometers from an edge of the inductor-forming region.

13. The semiconductor device according to claim 11 further comprising at least one second OD pattern disposed in the substrate or between the inductor wiring pattern and the substrate within the peripheral region.

14. The semiconductor device according to claim 11 wherein active devices are formed less than 20 micrometers away from the peripheral region.

15. The semiconductor device according to claim 1 wherein the shielding patterns act as a patterned ground shield.

16. The semiconductor device according to claim 1 wherein the shielding patterns are conductive shielding patterns.

17. The semiconductor device according to claim 1 wherein the shielding patterns are polysilicon shielding patterns.

18. The semiconductor device according to claim 1 wherein the shielding patterns are metal shielding patterns.

19. The semiconductor device according to claim 1 wherein the first OD pattern is further disposed near an active device around the semiconductor device.

20. The semiconductor device according to claim 19 wherein the shielding patterns and a gate of the active device are made of a same layer.
